(19) United States
(12) Patent Application Publication
(10) Pub. No.: US 2025/0048626 A1
(43) Pub. Date: Feb. 6, 2025

(54) MEMORY DEVICE AND MANUFACTURING METHOD OF THE MEMORY DEVICE

(71) Applicant: SK hynix Inc., Icheon-si Gyeonggi-do (KR)

(72) Inventors: Won Geun CHOI, Icheon-si Gyeonggi-do (KR); Jung Shik JANG, Icheon-si Gyeonggi-do (KR); Rho Gyu KWAK, Icheon-si Gyeonggi-do (KR); Seok Min CHOI, Icheon-si Gyeonggi-do (KR)

(73) Assignee: SK hynix Inc., Icheon-si Gyeonggi-do (KR)

(21) Appl. No.: 18/412,875

(22) Filed: Jan. 15, 2024

(30) Foreign Application Priority Data
Aug. 4, 2023 (KR) 10-2023-0102046

(51) Int. Cl. H10B 43/27; H10B 41/10; H10B 41/27; H10B 43/10

(52) U.S. Cl. CPC H10B 43/27; H10B 41/10; H10B 41/27; H10B 43/10

(57) ABSTRACT

A memory device may include a stack structure including a plurality of conductive layers and a plurality of interlayer insulating layers, which are alternately stacked along a first direction, an opening extending in the first direction from at least one conductive layer, among the plurality of conductive layers, in the stack structure, and a contact plug in the opening. The opening may include a protrusion portion protruding in a second direction intersecting the first direction.

### CROSS-REFERENCE TO RELATED APPLICATION

The present application claims priority under 35 U.S.C. § 119 (a) to Korean patent application number 10-2023-0102046 filed on Aug. 4, 2023, in the Korean Intellectual Property Office, the entire disclosure of which is incorporated by reference herein.

### BACKGROUND

### 1. Technical Field

The present disclosure generally relates to a memory device and a manufacturing method of the memory device, and more particularly, to a memory device including a memory block having a three-dimensional structure and a manufacturing method of the memory device.

### 2. Related Art

A memory device may include a nonvolatile memory device in which stored data is retained even when power supply is interrupted. The nonvolatile memory device may be divided into a two-dimensional structure and a three-dimensional structure according to a structure in which memory cells are arranged. Memory cells of a nonvolatile memory device having a two-dimensional structure may be arranged in a single layer above a substrate, and memory cells of a non-volatile memory device having a three-dimensional structure may be stacked in a vertical direction above a substrate. Since a degree of integration of the nonvolatile memory device having the three-dimensional structure is higher than a degree of integration of the nonvolatile memory device having the two-dimensional structure, electronic devices using the nonvolatile memory device having the three-dimensional structure have gained popularity.

### SUMMARY

In accordance with an aspect of the present disclosure, there is provided a memory device including: a stack structure including a plurality of conductive layers and a plurality of interlayer insulating layers, which are alternately stacked along a first direction; an opening extending in the first direction from at least one conductive layer, among the plurality of conductive layers, in the stack structure; and a contact plug in the opening, wherein the opening includes a protrusion portion protruding in a second direction intersecting the first direction.

In accordance with another aspect of the present disclosure, there is provided a method of manufacturing a memory device, the method including: forming a preliminary stack structure including first and second material layer sets each including at least one first material layer and at least one second material layer, the first and second material layer sets being stacked on each other; forming a first opening in the second material layer set and exposing the first material layer set; forming a protective layer on an inner wall of the first opening while the first opening is being formed; and forming a second opening in the first material layer set exposed through the first opening, wherein a width of a top end of the second opening is greater than a width of a bottom end of the first opening.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a diagram illustrating a memory device in accordance with an embodiment of the present disclosure.

FIG. 2 is a view schematically illustrating a memory device in accordance with an embodiment of the present disclosure.

FIG. 3 is a view illustrating a cell region and a contact region of a memory device in accordance with an embodiment of the present disclosure.

FIGS. 4A and 4B are views illustrating a structure of a memory device in accordance with an embodiment of the present disclosure.

FIGS. 5A to 5M are views illustrating a manufacturing method of a memory device in accordance with an embodiment of the present disclosure.

FIG. 6 is a view illustrating a structure of a memory device in accordance with another embodiment of the present disclosure.

FIG. 7 is a diagram illustrating a memory card system to which the memory device of the present disclosure is applied.

FIG. 8 is a diagram illustrating a Solid State Drive (SSD) system to which the memory device of the present disclosure is applied.

### DETAILED DESCRIPTION

The specific structural or functional description disclosed herein is merely illustrative for the purpose of describing embodiments according to the concept of the present disclosure. The embodiments according to the concept of the present disclosure can be implemented in various forms, and cannot be construed as limited to the embodiments set forth herein.

Hereinafter, exemplary embodiments of the present disclosure will be described in detail with reference to the accompanying drawings in order for those skilled in the art to be able to readily implement the technical spirit of the present disclosure.

Embodiments provide a memory device and a manufacturing method of the memory device, in which a width of contact plugs respectively connected to gate lines is constantly formed.

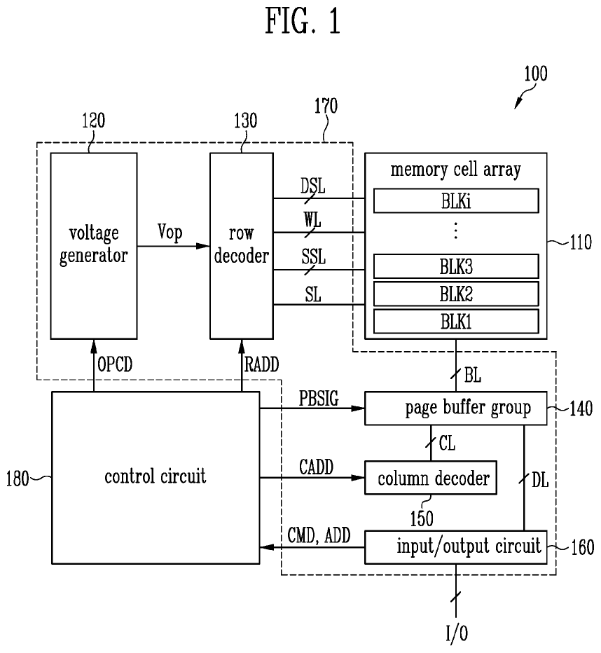

FIG. 1 is a diagram illustrating a memory device in accordance with an embodiment of the present disclosure.

Referring to FIG. 1, the memory device 100 may include a memory cell array 110, a peripheral circuit 170, and a control circuit 180.

The memory cell array 110 may include first to ith memory blocks BLK1 to BLKi. Each of the first to ith memory blocks BLK1 to BLKi may include memory cells capable of storing data. Drain select lines DSL, word lines WL, source select lines SSL, and a source line SL may be connected to each of the first to ith memory blocks BLK1 to BLKi, and bit lines BL may be commonly connected to the first to ith memory blocks BLK1 to BLKi.

The first to ith memory blocks BLK1 to BLKi may be formed in a three-dimensional structure. The memory blocks having the three-dimensional structure may include memory cells stacked in a vertical direction above a substrate.

The memory cells may store one-bit or two-or-more-bit data according to a program manner. For example, a manner in which one-bit data is stored in one memory cell may be referred to as a single level cell (SLC) manner, and a manner in which two-bit data is stored in one memory cells may be referred to as a multi-level cell (MLC) manner. A manner in which three-bit data is stored in one memory cell may be referred to as a triple level cell (TLC) manner, and a manner in which four-bit data is stored in one memory cell may be referred to as a quad level cell (QLC) manner. In addition, five-or-more-bit data may be stored in one memory cell.

The peripheral circuit 170 may be configured to perform a program operation for storing data, a read operation for outputting data stored in the memory cell array 110, and an erase operation for erasing data stored in the memory cell array 110. For example, the peripheral circuit 170 may include a voltage generator 120, a row decoder 130, a page buffer group 140, a column decoder 150, and an input/output circuit 160.

The voltage generator 120 may generate various operating voltages Vop used for a program operation, a read operation, or an erase operation in response to an operation code OPCD. For example, the voltage generator 120 may be configured to generate program voltages, turn-on voltages, turn-off voltages, negative voltages, precharge voltages, verify voltages, read voltages, pass voltages, or erase voltages in response to the operation code OPCD. The operating voltages Vop generated by the voltage generator 120 may be applied to drain select lines DSL, word lines WL, source select lines SSL, and a source line SL of a selected memory block through the row decoder 130.

The program voltages may be voltages applied to a selected word line, among word lines WL, in a program operation and may be used to increase a threshold voltage of memory cells connected to the selected word line. The turn-on voltages may be applied to the drain select lines DSL or the source select lines SSL and may be used to turn on drain select transistors or source select transistors. The turn-off voltages may be applied to the drain select lines DSL or the source select lines SSL and may be used to turn off the drain select transistors or the source select transistors. For example, the turn-off voltage may be set to 0V. The precharge voltages may be voltages higher than 0V and may be applied to the bit lines in a read operation. The verify voltages may be used in a verify operation for determining whether a threshold voltage of selected memory cells has been increased to a target level. The verify voltages may be set to various levels according to the target level and may be applied to a selected word line.

The read voltages may be applied to a selected word line in a read operation of selected memory cells. For example, the read voltages may be set to various levels according to a program manner of the selected memory cells. The pass voltages may be voltages applied to unselected word lines, among the word lines WL, in a program or read operation and may be used to turn on memory cells connected to the unselected word lines. The erase voltages may be used in an erase operation for erasing memory cells included in a selected memory block and may be applied to the source line SL.

The row decoder 130 may be configured to transmit the operating voltages Vop to drain select lines DSL, word lines WL, source select lines SSL, and a source line SL, which are connected to a selected memory block, according to a row address RADD. For example, the row decoder 130 may be connected to the voltage generator 120 through global lines and may be connected to the first to ith memory blocks BLK1 to BLKi through the drain select lines DSL, the word lines WL, the source select lines SSL, and the source line SL.

The page buffer group 140 may include page buffers (not shown) connected to each of the first to ith memory blocks BLK1 to BLKi. The page buffers (not shown) may be connected to the first to ith memory blocks BLK1 to BLKi, respectively, through the bit lines BL. In a read operation, in response to page buffer control signals PBSIG, the page buffers (not shown) may sense a current or a voltage of the bit lines BL, which varies according to threshold voltages of selected memory cells, and may temporarily store sensed data.

The column decoder 150 may be configured to transmit data between the page buffer group 140 and the input/output circuit 160 in response to a column address CADD. For example, the column decoder 150 may be connected to the page buffer group 140 through column lines CL and may transmit enable signals through the column lines. The page buffers (not shown) included in the page buffer group 140 may receive or output data through data lines DL in response to the enable signals.

The input/output circuit 160 may be configured to receive or output a command CMD, an address ADD, or data through input/output lines I/O. For example, the input/output circuit 160 may transmit, through the input/output lines I/O, a command CMD and an address ADD, which are received from an external controller, to the control circuit 180 and may transmit data received from the external controller to the page buffer group 140 through the input/output lines I/O. Alternatively, the input/output circuit 160 may output data transferred from the page buffer group 140 to the external controller through the input/output lines I/O.

The control circuit 180 may output at least one of an operation code OPCD, the row address RADD, the page buffer control signals PBSIG, and the column address CADD in response to the command CMD and the address ADD. For example, when the command CMD input to the control circuit 180 is a command corresponding to a program operation, the control circuit 180 may control the peripheral circuit 170 to perform a program operation of a memory block selected by the address ADD. When the command CMD input to the control circuit 180 is a command corresponding to a read operation, the control circuit 180 may control the peripheral circuit 170 to perform the read operation of the selected memory block selected and output read data. When the command CMD input to the control circuit 180 is a command corresponding to an erase operation, the control circuit 180 may control the peripheral circuit 170 to perform the erase operation of the selected memory block.

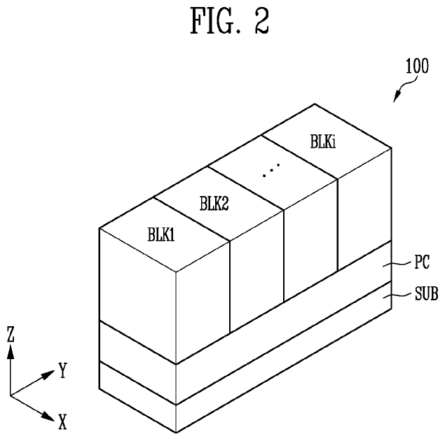

FIG. 2 is a view schematically illustrating a memory device in accordance with an embodiment of the present disclosure.

Referring to FIG. 2, the memory device 100 may include a peripheral circuit structure PC and memory blocks BLK1 to BLKi, which are disposed on a substrate SUB. The memory blocks BLK1 to BLKi may overlap with the peripheral circuit structure PC.

The substrate SUB may be a single crystalline semiconductor layer. For example, the substrate SUB may be a bulk silicon substrate, a silicon on insulator substrate, a germanium substrate, a germanium on insulator substrate, a silicon-germanium substrate, or an epitaxial thin film formed through a selective epitaxial growth process.

The peripheral circuit structure PC may include a row decoder (130 shown in FIG. 1), a column decoder (150 shown in FIG. 1), a page buffer group (140 shown in FIG. 1), a control circuit (180 shown in FIG. 1), and the like, which constitute a circuit for controlling operations of the memory blocks BLK1 to BLKi. For example, the peripheral circuit structure PC may include an NMOS transistor, a PMOS transistor, a resistor, a capacitor, and the like, which are electrically connected to the memory blocks BLK1 to BLKi. The peripheral circuit structure PC may be disposed between the substrate SUB and the memory blocks BLK1 to BLKi.

Each of the memory blocks BLK1 to BLKi may include a source structure, bit lines, cell strings electrically connected to the source structure and the bit lines, word lines electrically connected to the cell strings, and select lines electrically connected to the cell strings. Each of the cell strings may include memory cells and select transistors, which are connected in series by a cell plug. Each of the select lines may be used as a gate electrode of a select transistor corresponding thereto, and each of the word lines may be used as a gate electrode of a memory cell corresponding thereto.

In another embodiment, the substrate SUB, the peripheral circuit structure PC, and the memory blocks BLK1 to BLKi may be stacked in a reverse order of the order shown in FIG. 2. For example, the peripheral circuit structure PC may be disposed on the memory blocks BLK1 to BLKi.

In another embodiment, unlike as shown in FIG. 2, the peripheral circuit structure PC may be disposed on a partial region of the substrate SUB, which does not overlap with the memory blocks BLK1 to BLKi. For example, the peripheral circuit structure PC and the memory blocks BLK1 to BLKi may be respectively disposed on regions of the substrate SUB, which do not overlap with each other.

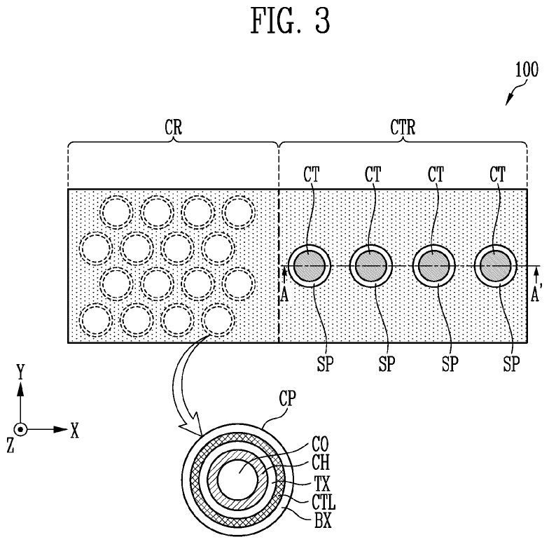

FIG. 3 is a view illustrating a cell region and a contact region of a memory device in accordance with an embodiment of the present disclosure. FIG. 3 is a plan view illustrating a layout of a cell region CR and a contact region CTR of the memory device 100.

Referring to FIG. 3, the memory device may include the cell region CR and the contact region CTR. For example, the contact region CTR may extend in an X direction from the cell region CR. Unlike the illustration of FIG. 3, the contact region CTR may extend in a Y direction from the cell region CR or may extend in the X direction and the Y direction. In addition, the cell region CR and the contact region CTR may be variously disposed.

Cell plugs CP may be located in the cell region CR. The cell plugs CP may be formed in the cell region CR. Contact plugs CT may be located in the contact region CTR. The contact plugs CT may be formed in the contact region CTR.

The cell plugs CP may be arranged along the X direction and the Y direction in the cell region CR. Each of the cell plugs CP may extend in a Z direction. Each of the cell plugs CP may include a blocking layer BX, a charge trap layer CTL formed along an inner wall of the blocking layer BX, a tunnel insulating layer TX formed along an inner wall of the charge trap layer CTL, a channel layer CH formed along an inner wall of the tunnel insulating layer TX, or a core pillar CO inside the channel layer CH, or include a combination of at least two thereof. The blocking layer BX and the tunnel insulating layer TX may be formed of an oxide layer. For example, the blocking layer BX and the tunnel insulating layer TX may be formed of a silicon oxide layer or a silicon nitride layer, or be formed of a combination thereof. The charge trap layer CTL may be formed of a nitride layer or a variable resistance material. The channel layer CH may be formed of a conductive layer, e.g., a doped silicon layer. The channel layer CH may be replaced with an electrode structure. The core pillar CO may be formed of an insulating layer or a conductive layer. Each of the blocking layer BX, the charge trap layer CTL, the tunnel insulating layer TX, the channel layer CH, and the core pillar CO may extend in the Z direction Z. A capping layer for improving electrical characteristics of select transistors included in each cell string may be further formed on the top of the core pillar CO.

The contact plugs CT may be arranged along the X direction in the contact region CTR. Unlike the illustration of FIG. 3, the contact plugs CT may be arranged along the Y direction in the contact region CTR. Alternatively, some of the contact plugs CT may be arranged along the X direction while other contact plugs CT may be arranged along the Y direction. Each of the contact plugs CT may extend in the Z direction.

Spacers SP may be formed on outer walls of the contact plugs CT. The spacers SP may surround side surfaces of the contact plugs CT. Sidewalls of the contact plugs CT might not be exposed by the spacers SP.

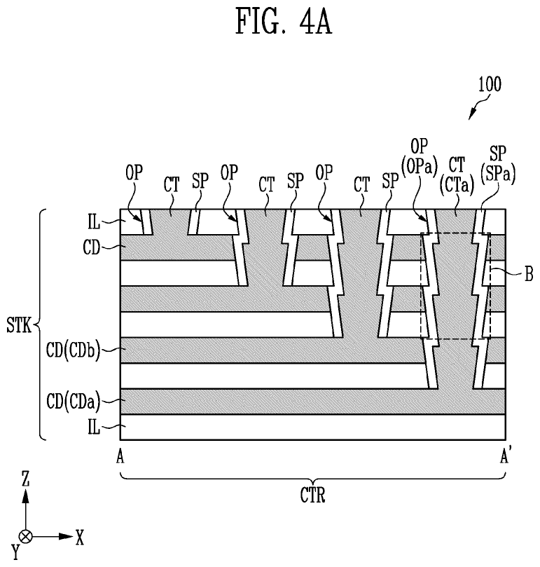

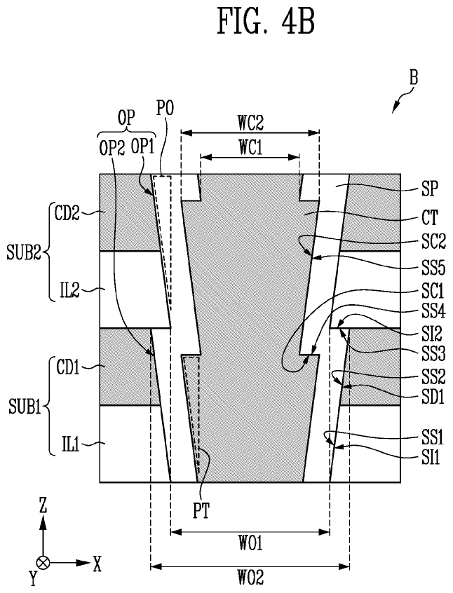

The number of cell plugs CP and the contact plugs CT are not limited to the illustration of FIG. 3. For example, the number of contact plugs CT may vary according to a stacked number of layers included in the first memory block BLK1. In addition, the positions of the cell plugs CP and the contact plugs CT are not limited to the illustration of FIG. 3, and the cell plugs CP and the contact plugs CT may be located at various positions as long as the cell plugs CP and the contact plugs CT include features described in FIGS. 4A and 4B.

FIGS. 4A and 4B are views illustrating a structure of a memory device in accordance with an embodiment of the present disclosure. FIG. 4A is a sectional view illustrating a section taken along the line A-A′ shown in FIG. 3. FIG. 4B is an enlarged view of A shown in FIG. 4A.

Referring to FIG. 4A, the memory device 100 may include a stack structure STK in which conductive layers CD and interlayer insulating layers IL are alternately stacked. The stack structure STK may include the conductive layers CD and the interlayer insulating layers IL, which are alternately stacked along the Z direction. The stack structure STK may extend in the X direction and the Y direction. The conductive layers CD may be formed of tungsten (W), cobalt (Co), nickel (Ni), molybdenum (Mo), silicon (Si) or poly-silicon (poly-Si) or may be formed of a combination of at least two thereof. The interlayer insulating layers IL may be formed of an oxide layer (e.g., a silicon oxide layer).

FIG. 4A illustrates a contact region CTR in the stack structure STK. In the present disclosure, the contact region CTR might not have any stepped structure. Stacked numbers of the conductive layers CD and the interlayer insulating layers IL, which are included in the stack structure STK in the contact region CTR, may be substantially the same regardless of the positions on an XY plane. Lengths of the conductive layers CD included in the stack structure STK in the X direction (or lengths of the conductive layers CD in the Y direction) may be substantially the same. For example, a length of any one conductive layer CDa in the X direction and a length of another conductive layer CDb in the X direction may be substantially the same.

The stack structure STK may include openings OP. The openings OP may be formed in the stack structure STK. The openings OP may respectively correspond to the conductive layers CD included in the stack structure STK. The openings OP may be in contact with top surfaces of the conductive layers CD, respectively. For example, any one opening OPa may be in contact with a top surface of the one conductive layer CDa. Each of the openings OP may extend along the Z direction. The openings OP may extend in the Z direction from the conductive layers CD. For example, the one opening OPa may extend in the Z direction from the one conductive layer CDa. A section of each of the openings OP may have a circular shape, an elliptical shape, or other various shapes.

Contact plugs CT may be respectively formed in the openings OP. The contact plugs CT may be in contact with the conductive layers CD, respectively. The contact plugs CT may be electrically connected to the conductive layers CD, respectively. For example, any one contact plug CTa may be in contact with the one conductive layer CDa and may be electrically connected to the one conductive layer CDa. The contact plugs CT may extend in the openings OP, respectively. The contact plugs CT may extend in the Z direction from the top surfaces of the conductive layers CD. For example, the one contact plug CTa may extend in the Z direction from the top surface of the one conductive layer CDa. The contact plugs CT may penetrate at least one conductive layer CD and at least one interlayer insulating layer IL. Each of the contact plugs CT may penetrate a different number of conductive layers CD. For example, the identified contact plug CTa in FIG. 4A may penetrate an additional conductive layer CDb, which is above the one conductive layer CDa, compared to the adjacent contact plug CT that penetrates the conductive layer, which is above the conductive layer CDb. The contact plugs CT may be formed of tungsten (W), cobalt (Co), nickel (Ni), molybdenum (Mo), silicon (Si) or poly-silicon (poly-Si) or may be formed of a combination of at least two thereof.

Spacers SP may be formed along inner walls of the openings OP. The spacers SP may cover the inner walls of the openings OP. The spacers SP may conformally cover the inner walls of the openings OP. For example, any one spacer SPa formed in the one opening OPa may substantially have the same thickness regardless of the depth in the corresponding opening OPa. The spacers SP may cover sidewalls of the contact plugs CT. The spacers SP may surround side surfaces of the contact plugs CT. The spacers SP may be filled with contact plugs CT. For example, the contact plugs CT may be formed in regions surrounded by the spacers SP.

The spacers SP may be formed between the inner walls of the openings OP and the contact plugs CT. The spacers SP may allow the contact plugs CT to be spaced apart from at least one conductive layer CD and/or insulating layer IL. For example, the one spacer SPa may allow the one contact plug CTa to be spaced apart from the another conductive layer CDb disposed above the one conductive layer CDa. Therefore, each of the contact plugs CT may be electrically connected to a conductive layer CD which becomes a target, and be electrically isolated from the other conductive layers CD through a spacer SP. The spacers SP may be formed of a material (e.g., an oxide layer, a nitride layer, an oxynitride layer, or an oxide layer doped with a metal) capable of insulating the contact plugs CT from the conductive layers CD.

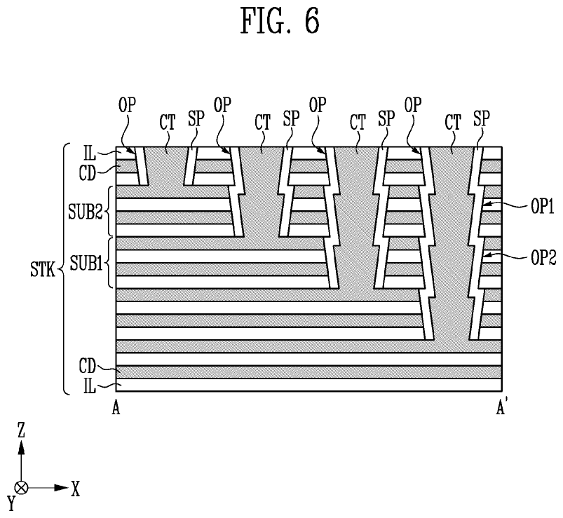

Referring to FIG. 4B, the stack structure STK may include a first sub-stack structure SUB1 including a first conductive layer CD1 and a first interlayer insulating layer IL1 and a second sub-stack structure SUB2 including a second conductive layer CD2 and a second interlayer insulating layer IL2. The second sub-stack structure SUB2 may be disposed on the first sub-stack structure SUB1. In FIG. 4B, it is illustrated that each of the first and second sub-stack structures SUB1 and SUB2 includes a pair of a conductive layer CD and an interlayer insulating layer IL. However, this is merely an example, and the scope of the present disclosure is not limited thereto. For example, each of the first and second sub-stack structures SUB1 and SUB2 may include two or more conductive layers and two or more interlayer insulating layers, which are alternately stacked. However, a conductive layer CD may be disposed in an uppermost layer of each of the first and second sub-stack structures SUB1 and SUB2, and an interlayer insulating layer IL may be disposed in a lowermost layer of each of the first and second sub-stack structures SUB1 and SUB2. An embodiment in which a sub-stack structure includes two or more conductive layers CD and two or more interlayer insulating layers IL will be described later with reference to FIG. 6.

Referring to FIGS. 4A and 4B, the first and second sub-stack structures SUB1 and SUB2, penetrated by a contact plug CT (e.g., CTa), may contact and protrude upward from any one conductive layer (e.g., the conductive layer CDa shown in FIG. 4A).

Referring to FIG. 4B, an opening OP may include a first opening OP1 and a second opening OP2 below the first opening OP1. The first opening OP1 may be located above the second opening OP2 in the Z direction. The second opening OP2 may extend in a downward direction from the first opening OP1. The second sub-stack structure SUB2 may include the first opening OP1, and the first sub-stack structure SUB1 may include the second opening OP2. The first opening OP1 may penetrate the second sub-stack structure SUB2, and the second opening OP2 may penetrated the first sub-stack structure SUB1. The first opening OP1 and the second opening OP2 are merely divided for convenience of description and may be components that are not physically isolated from each other.

Each of the first opening OP1 and the second opening OP2 may have a width of a top end thereof, which is formed to be greater than a width of a bottom end thereof. For example, a bottom end of the first opening OP1 may have a first width WO1, and a top end of the first opening OP1 may have a second width WO2, which is greater than the first width WO1. In addition, a bottom end of the second opening OP2 may have the first width WO1, and a top end of the second opening OP2 may have the second width WO2, which is greater than the first width WO1.

The width of the top end of the second opening OP2 may be greater than the width of the bottom end of the first opening OP1. For example, the top end of the second opening OP2 may have the second width WO2, and the bottom end of the first opening OP1 may have the first width WO1, which is less than the second width WO2. That is, a width of the opening OP and its relationship to a depth of the opening OP will be described. For example, the width of the first opening OP1 may decrease (e.g., decrease from WO2 to WO1) when measuring the thickness from the top end to the bottom end of the first opening OP1 but may increase again (e.g., increase from WO1 to WO2) at a specific point (i.e., when transitioning from the first opening OP1 to the subsequent opening below the one opening, the second opening OP2). Therefore, a sidewall of the opening OP may have an uneven surface. An inner wall of the opening may be formed to have similar unevenness.

The opening OP may include a protrusion portion protruding toward directions (e.g., the X direction and the Y direction) intersecting the Z direction. The protrusion portion PO may protrude into the stack structure STK. The first opening OP1 may be formed with the protrusion portion PO such that the top end of the first opening OP1 may be wider than the bottom end of the first opening OP1. Also, the first opening OP1 may be formed with the protrusion portion PO such that the top end of the first opening OP1 protrudes into the stack structure STK as compared with the bottom end of the first opening OP1. Similarly, the second opening OP2 may be formed with the protrusion portion PO such that the top end of the second opening OP2 may be wider than the bottom end of the second opening OP2 and the bottom end of the first opening OP1. Also, the second opening OP2 may be formed with the protrusion portion PO such that the top end of the second opening OP2 protrudes into the stack structure STK as compared with each of the bottom end of the second opening OP2 and the bottom end of the first opening OP1. The protrusion portion PO may include a side surface having a slope. A section of the protrusion portion PO may include a right-angled triangular shape. Because of the protrusion portion OP, each of the first and second openings OP1 and OP2 may include a sidewall having a slope. Each of the first and second openings OP1 and OP2 may include an inclined surface that becomes closer to the center of the opening OP as the depth thereof increases.

In FIG. 4B, it is illustrated that the width (e.g., WO2) of the top end of the first opening OP1 and the width (e.g., WO2) of the top end of the second opening OP2 are the same, and the width (e.g., WO1) of the bottom end of the first opening OP1 and the width (e.g., WO1) of the bottom end of the second opening OP2 are the same. However, the scope of the present disclosure is not limited thereto. For example, the width of the top end of the second opening OP2 may be less than the width of the top end of the first opening OP1 and may be greater than the width of the bottom end of the first opening OP1.

A spacer SP may be formed along the inner wall of the opening OP. The spacer SP may be conformally formed on the inner wall of the opening OP. For example, a shape of the inner wall of the spacer SP may correspond to a shape of an outer wall of the spacer SP. Since the inner wall of the opening has an uneven surface, the inner wall of the spacer SP may also have an uneven surface.

An outer sidewall of the spacer SP may be in contact with an inner wall of the stack structure STK, which is exposed by the opening OP. For example, a first surface SS1 of the spacer SP in the second opening OP2 may be in contact with a first surface SI1 of the first interlayer insulating layer IL1. In addition, a second surface SS2 of the spacer SP in the second opening OP2 may be in contact with a first surface SD1 of the first conductive layer CD1.

A portion of a top surface of the second opening OP2 may be in contact with a bottom surface of the second sub-stack structure SUB2. For example, a third surface SS3 as a top surface of the spacer SP in the second opening OP2 may be in contact with a second surface SI2 as a bottom surface of the second interlayer insulating layer IL2. Since the width (e.g., the second width WO2) of the top end of the second opening OP2 is greater than the width (e.g., the first width WO1) of the bottom end of the first opening OP1, the top end of the second opening OP2 may extend to the bottom end of the first opening OP1, this extension being another portion of the second opening OP2 that is in contact with the stack structure STK.

In addition, an interface between the first sub-stack structure SUB1 and the second sub-stack structure SUB2 may correspond to an interface between the second opening OP2 and the first opening OP1. The interface between the first and second sub-stack structures SUB1 and SUB2 and the interface between the second and first openings OP2 and OP1 may be formed at the same level.

A contact plug CT may be formed inside the spacer SP. The contact plug CT may fill the rest of the opening OP that has not been filled by the spacer SP. An outer wall of the contact plug CT may be in contact with the inner wall of the spacer SP. Since the inner wall of the spacer SP has an uneven surface, a sidewall of the contact plug CT may also have an uneven surface. Therefore, a width of the contact plug CT may vary according to the depth of the opening OP. For example, the contact plug CT at a first position may have a first width WC1, and the contact plug CT at a second position under the first position may have a second width WC2, which is greater than the first width WC1.

The contact plug CT may include a protrusion portion PT protruding toward directions (e.g., the X direction and the Y direction) intersecting the Z direction. The protrusion portion PT of the contact plug CT may protrude toward the stack structure STK. The protrusion portion PT of the contact plug CT may include a side surface having a slope. A section of the protrusion portion PT may have a right-angled triangular shape. Because of the protrusion portion PT, the width of the contact plug CT may vary according to the height at which the contact plug CT is measured.

The inner wall of the spacer SP may be in contact with the sidewall of the contact plug CT. For example, extending in the X-Y plane, a fourth surface SS4 of the inner wall of the spacer SP may be in contact with a first surface SC1 of the outer wall of the contact plug CT. In addition, a fifth surface SS5 in the inner wall of the spacer SP may be in contact with a second surface SC2 of the contact plug CT.

The protrusion portion PT of the contact plug CT may be formed to be lower in the Z direction than the protrusion portion PO of the opening OP. Since the spacer SP is conformally formed on the inner wall of the opening OP, a position of the protrusion portion PT of the contact plug CT may be lower than a position of the protrusion portion PO of the opening OP. For example, a top surface of the protrusion portion PT of the contact plug CT in the second opening OP2 may be lower than a top surface of the protrusion portion PO included in the second opening OP2. Therefore, an interface between the fourth surface SS4 of the spacer SP and the first surface SC1 of the contact plug CT may be lower than an interface between the third surface SS3 of the spacer SP and the second surface SI2 of the second interlayer insulating layer IL2.

Referring to FIGS. 4A and 4B, since the sidewall of the opening OP includes unevenness, the width of the opening OP does not constantly decrease but may repeatedly increase and decrease as the depth of the opening OP increases. Therefore, a difference between a width of a top end of the opening OP and a width of a bottom end of the opening OP may decrease as compared with the existing openings. For example, the width of the opening OP in accordance with the present disclosure may have a small difference the top end and the bottom end thereof, as compared with a case where the width of the opening decreases as the depth of the opening increases.

In addition, although the widths of each opening changes based on the height at which the opening is measured, the change may be substantially uniform between each opening. For example, the openings OP shown in FIG. 4A have different depths in the Z direction, but each opening OP may have substantially the same width at a specific relative height, relative to the opening itself, not the general Z direction. Therefore, a variation of widths or thicknesses may be small between the openings OP included in the memory device 100.

As described above, in accordance with the present disclosure, since a difference between the width of the upper end and the width of the bottom end in each of the openings OP is small, a difference between the width of the upper end and the width of the bottom end in each of the contact plugs CT formed in the openings OP may also decrease as compared with the existing contact plugs. Also, in accordance with the present disclosure, since a difference in width between the openings OP is small, a difference in width between the contact plugs CT formed in the openings OP may also decrease as compared with the existing contact plugs.

When the openings OP have a constant width, a width with which gate lines (e.g., the conductive layers CD) included in the memory device 100 penetrate may also be constant. When the gate lines (e.g., the conductive layers CD) penetrate with a constant width, it can be advantageous for the memory device 100 to control dispersion of resistances of the gate lines. Furthermore, various effects to be derived by characteristics described in the present disclosure can be exhibited.

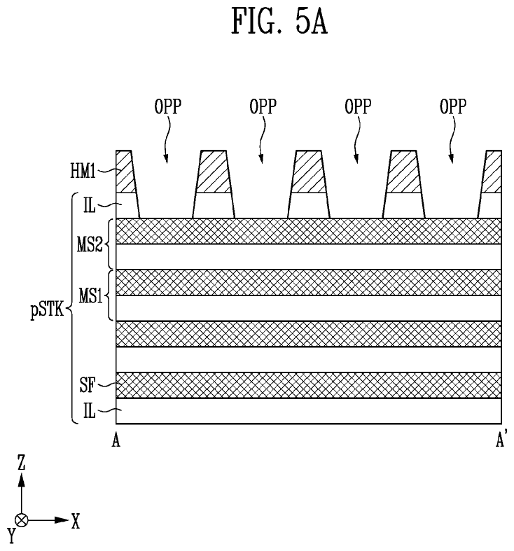

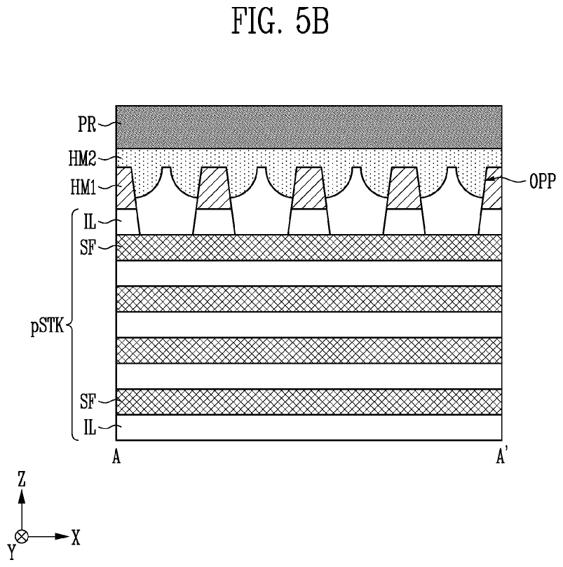

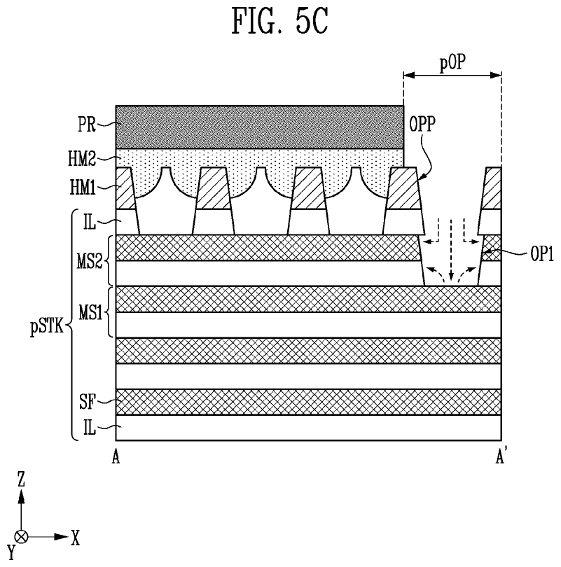

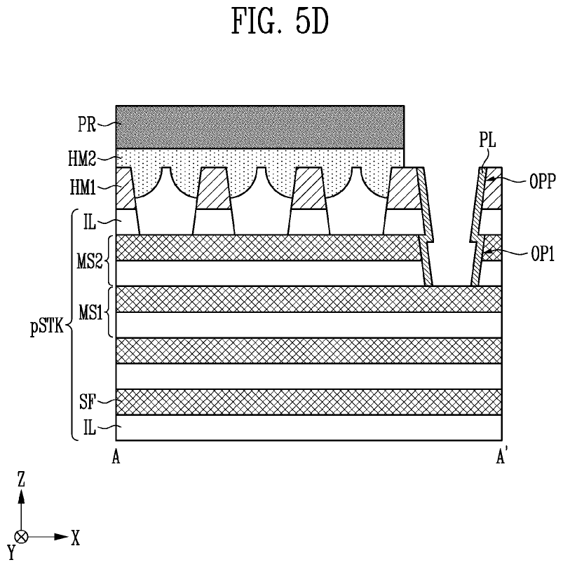

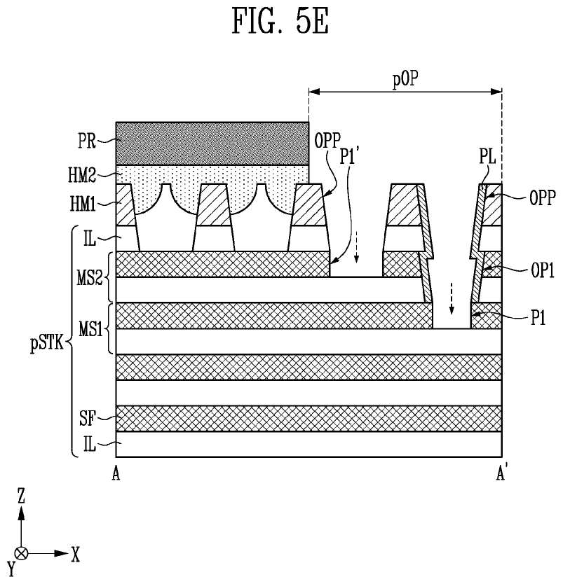

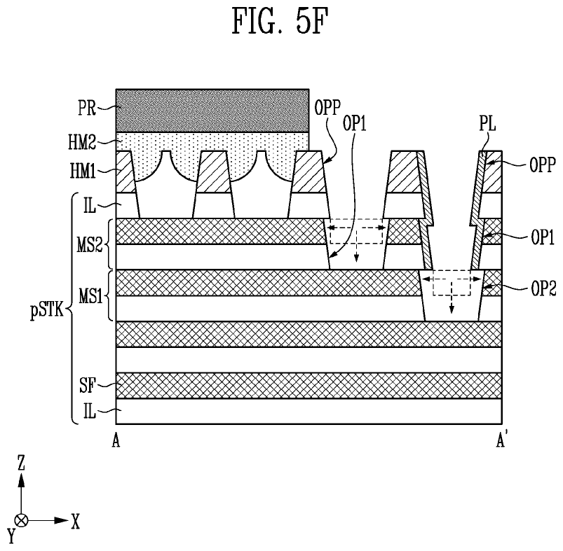

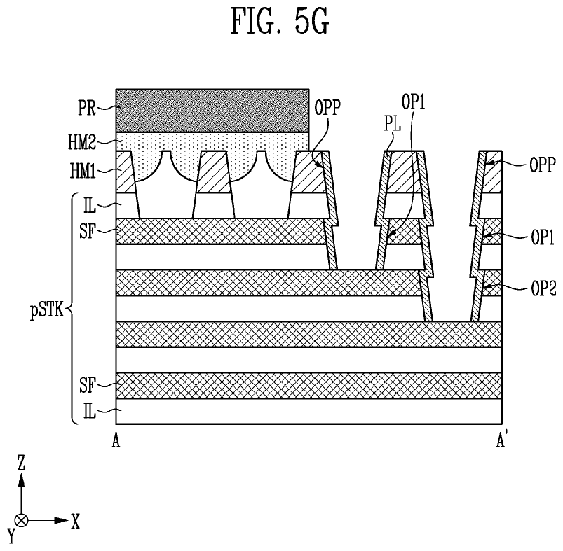

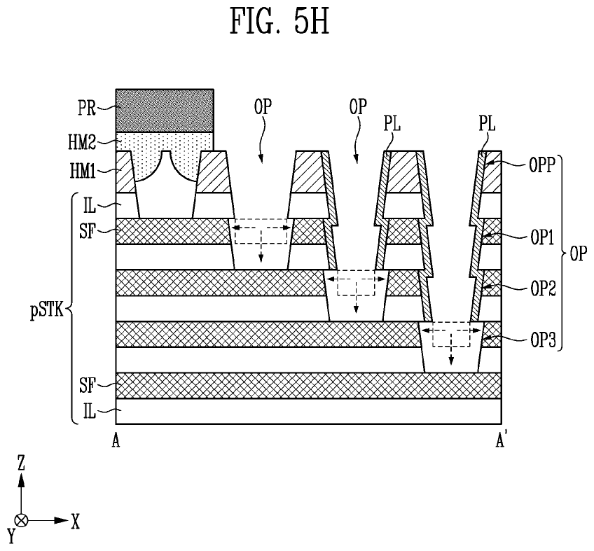

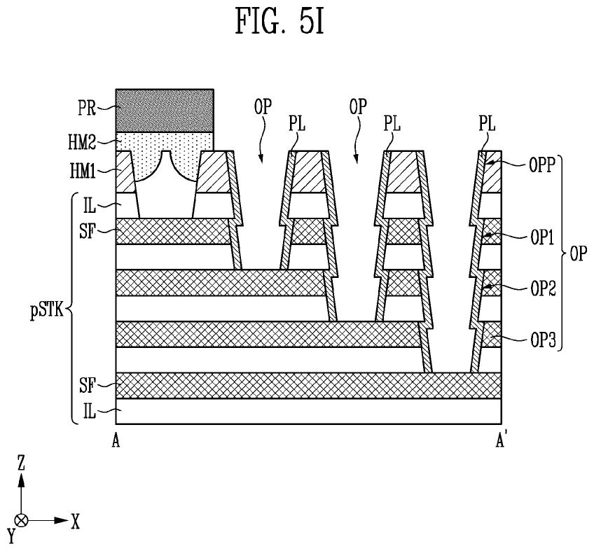

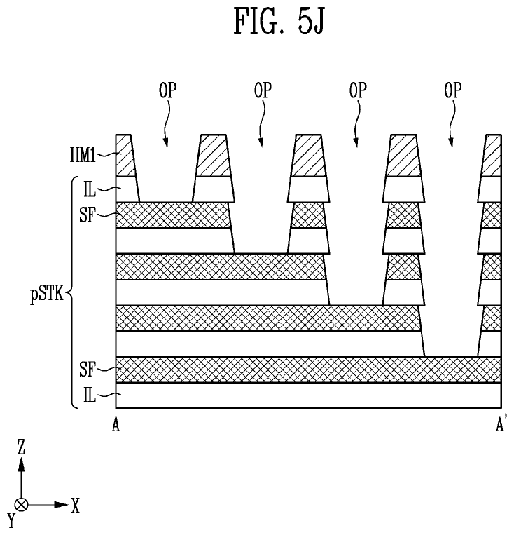

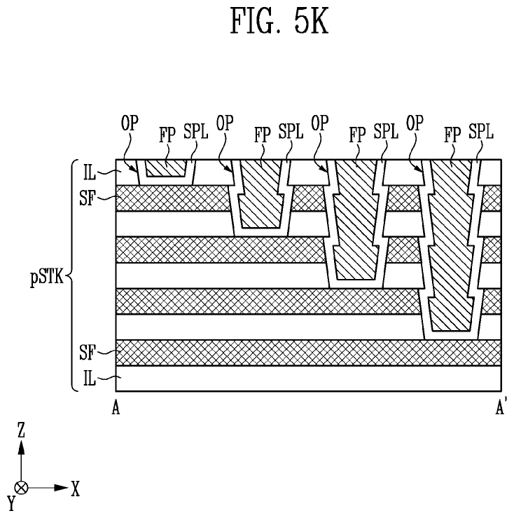

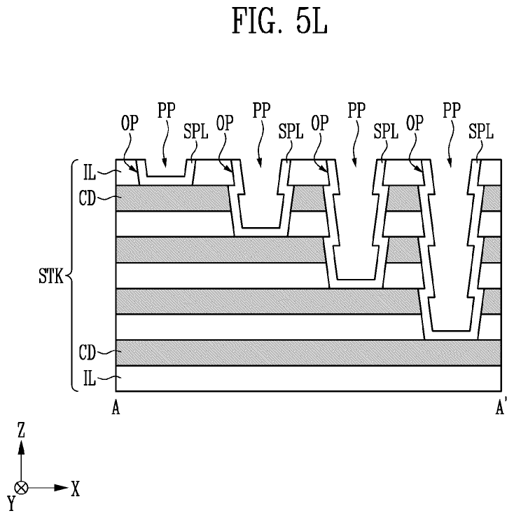

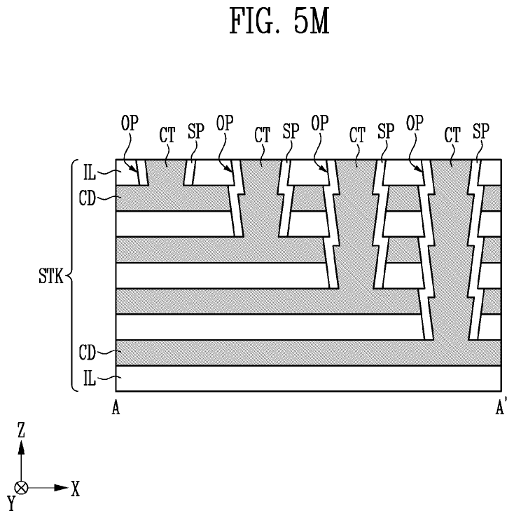

FIGS. 5A to 5M are views illustrating a manufacturing method of a memory device in accordance with an embodiment of the present disclosure. FIGS. 5A to 5M are sectional views illustrating the section taken along line A-A′ shown in FIG. 3.

Referring to FIG. 5A, a preliminary stack structure pSTK may be formed in which first material layers IL and second material layers SF are alternately stacked. The preliminary stack structure pSTK may include first and second material layer sets MS1 and MS2, each including at least one first material layer IL and at least one second material layer SF. The second material layer set MS2 may be stacked on the first material layer set MS1. In FIG. 5A, each of the first and second material layer sets MS1 and MS2 may include a pair of a first material layer IL and a second material layer SF. However, the present disclosure is not limited thereto, and each of the first and second material layer sets MS1 and MS2 may include two or more pairs of first material layers IL and the second material layers SF.

The first material layer IL may be formed of an insulating material. For example, the first material layer IL may be formed of an oxide layer (e.g., a silicon oxide layer). The second material layer SF may be formed of a material that can be selectively removed in a subsequent process. The second material SF may be formed of a material having an etch selectivity that is different from an etch selectivity of the first material layer IL. For example, the second material layer SF may be formed of a nitride layer.

A first hard mask HM1 may be formed on the preliminary stack structure pSTK. The first hard mask HM1 may cover a first material layer IL at an uppermost end of the preliminary stack structure pSTK. The first hard mask HM1 may be deposited with a thickness that is greater than a thickness of each of the first material layers IL and the second material layers SF. The first hard mask HM1 may be formed of poly-silicon.

Preliminary openings OPP may be formed, which penetrate the first hard mask HM1. The preliminary openings OPP may be formed to penetrate the first hard mask HM1 and at least one first material layer IL. For example, the preliminary openings OPP may be formed to expose the second material layer set MS2. Each of the preliminary openings OPP may be formed to have a top end that is wider than a bottom end. An anisotropic dry etching process may be performed to form the preliminary openings OPP at specified positions.

Referring to FIG. 5B, a second hard mask HM2 may be formed on the first hard mask HM1. The second hard mask HM2 may cover the first hard mask HM1 and the preliminary openings OPP. While the second hard mask HM2 is being formed, an overhang may occur in which the second hard mask HM2 extends onto inner walls of the preliminary openings OPP. However, the second hard mask HM2 might not completely fill the preliminary openings OPP but may fill a portion of a top end of each of the preliminary openings OPP. The second hard mask HM2 may be deposited with a thickness that is less than the thickness of the first hard mask HM1. The second hard mask HM2 may be formed of a carbon layer.

A photoresist PR may be formed on the second hard mask HM2. The photoresist PR may cover the second hard mask HM2. The photoresist PR may be formed of a material having chemical characteristics changed by light.

Referring to FIG. 5C, a portion of the photoresist PR may be removed. For example, a partial region of the photoresist PR may be removed through a photolithography process.

A portion of the second hard mask HM2 may be exposed through a photo opening pOP in which the portion of the photoresist PR is removed. The portion of the second hard mask HM2, which is exposed through the photo opening pOP, may be removed through an etching process. As the portion of the second hard mask HM2 is removed, at least one of the preliminary openings OPP may be opened. As the at least one preliminary opening OPP is opened, one region of the preliminary stack structure pSTK may be exposed. For example, a portion of a top surface of the second material layer set MS2 may be exposed through the preliminary opening OPP.

A first opening OP1 may be formed in the preliminary stack structure pSTK through the preliminary opening OPP. The portion of the second material layer set MS2, which is exposed through the preliminary opening OPP, may be etched. The first opening OP1 may overlap with the bottom of the preliminary opening OPP and may extend in a downward direction from the preliminary opening OPP. The first opening OP1 exposing the first material layer set MS1 may be formed in the second material layer set MS2. The first opening OP1 may be formed in the second material layer set MS2. The first opening OP1 may penetrate the second material layer set MS2. A width of a top end of the first opening OP1 may be greater than a width of a bottom end of the preliminary opening OPP. Also, the width of the top end of the first opening OP1 may be greater than a width of a bottom end of the first opening OP1. At least one process, among anisotropic dry etching, isotropic wet etching, and reactive ion etching, may be performed to form the first opening OP1 through the preliminary opening OPP.

Referring to FIG. 5D, a protective layer PL may be formed on an inner wall of the preliminary opening OPP and an inner wall of the first opening OP1. While the first opening OP1 is being formed, the protective layer PL may be formed along a sidewall of the first opening OP1 and a sidewall of the preliminary opening OPP. The protective layer PL may cover the sidewall of the first opening OP1 but might not cover a bottom surface of the first opening OP1. The protective layer PL may be formed of polymer. A byproduct of an etching process, which is generated while the first opening OP1 is being formed by etching the second material layer set MS2, may be the protective layer PL, which is deposited in an opening (e.g., OPP and OP1). That is, although a separate deposition process for forming the protective layer PL is not performed, a byproduct generated by the first hard mask layer HM1 in the etching process may remain on the sidewall of the first opening OP1, thereby forming the protective layer PL. During the etching process for forming the first opening OP1, the protective layer PL may be formed by controlling the exhaust amount of a gas used for etching. For example, during the etching process for forming the first opening OP1, when an exhaust amount of a source gas used for etching is less than or equal to a threshold value, the byproduct of the etching process might not be discharged outside of a chamber but may remain on the sidewall of the first opening OP1.

Referring to FIG. 5E, as a portion of the photoresist PR is removed through a photolithography process, a width of the photo opening pOP of the photoresist PR may be widened, and an etching process for removing a portion of the second hard mask HM2 exposed through the photo opening pOP is widened. Therefore, the preliminary opening OPP may be additionally opened. Openings OP of which depths are different from each other as shown in FIG. 4A may be formed through a stepwise photolithography process of the photoresist PR and a stepwise etching process of the second hard mask HM2.

First, an opening OP shown at the rightmost side in FIGS. 5A to 5M will be described. A first region P1 may be formed, which extends from the preliminary opening OPP and the first opening OP1 in the preliminary stack structure pSTK. The first region P1 may be opened by etching the second material layer SF of the first material layer set MS1 exposed through the first opening OP1. For example, the second material layer SF of the first material layer set MS1 may be exposed through the bottom surface of the first opening OP1, and the exposed second material layer SF may be etched. A width of the first region P1 may be constant. A width of a top end of the first region P1 may be equal to a width of the first material layer set MS1 exposed as the protective layer PL is not formed. An anisotropic dry etching process or a reactive ion etching process may be performed to form the first region P1 through the first opening OP1.

Referring to FIG. 5F, a second opening OP2, further extended than the first region P1, may be formed in the preliminary stack structure pSTK. The depth of the first region P1 may be extended by etching the first material layer IL of the first material layer set MS1 through the first region P1. In addition, the width of the first region P1 may be extended by etching the second material layer SF of the first material layer set MS1 through the first region P1. While the first material layer IL is etched through the first region P1, the second material layer SF may also be partially etched by an etch selectivity. Therefore, the second opening OP2 may have a width that is extended compared to the first region P1, and a top end of the second opening OP2 may have a width that is greater than the width of the bottom end of the first opening OP1.

The second opening OP2 may be formed in the first material layer set MS1. The second opening OP2 may penetrate the first material layer set MS1. The second opening OP2 may overlap with the first opening OP1 and the preliminary opening OPP. The second opening OP2 may extend in a downward direction from the preliminary opening OPP and the first opening OP1. An anisotropic etching process may be performed to form the second opening OP2 by extending the first region P1.

Referring to FIGS. 5D to 5F, while the second opening OP2 is formed through the first opening OP1, an increase in width of the first opening OP1 may be partially suppressed by the protective layer PL. While the material layers SF and IL included in the preliminary stack structure pSTK are etched through the first opening OP1, the protective layer PL may protect the sidewall of the first opening OP1. For example, while the second opening OP2 is being formed through the first opening OP1, the width of the first opening OP1 may be constantly maintained. Therefore, the bottom end of the first opening OP1 may have a width that is less than the width of the top end of the second opening OP2.

Referring to FIG. 5G, a protective layer PL may be formed on an inner wall of the second opening OP2. While the second opening OP2 is formed, the protective layer PL may be formed along the sidewall of the second opening OP2. The protective layer PL may cover the sidewall of the second opening OP2 but might not cover a bottom surface of the second opening OP2. The protective layer PL may be formed of polymer. For example, a byproduct of an etching process, which is generated while the second opening OP2 is formed by etching the first material layer set MS1, may be deposited as the protective layer PL in the second opening OP2. The byproduct generated while the second opening OP2 is being formed may be deposited even on the sidewall of the preliminary opening OPP or the sidewall of the first opening OP1 in addition to the sidewall of the second opening OP2.

As described with reference to FIG. 5E, an opening OP to the left of the rightmost opening in FIGS. 5A to 5M will be described. A first region P1′ extending from a preliminary opening OPP may be formed in the preliminary stack structure pSTK. The first region P1′ may be opened by etching the second material layer SF of the second material layer set MS2 exposed through the preliminary opening OPP. The first region P1′ extending from the preliminary opening OPP may have a width that is greater than the width of the first region P1 extending from the first opening OP1.

Referring to FIG. 5F, a first opening OP1, further extended than the first region P1′, may be formed in the preliminary stack structure pSTK. The first opening OP1 may be formed in the second material layer set MS2. The depth of the first region P1′ may be extended by etching the first material layer IL of the second material layer set MS2 through the first region P1′. In addition, the width of the first region P1′ may be extended by etching the second material layer SF of the second material layer set MS2 through the first region P1′. Since the first opening OP1 has a width that is extended compared to the first region P1′, a top end of the first opening OP1 may have a width that is greater than a width of a bottom end of the preliminary opening OPP.

Referring to FIG. 5G, a protective layer PL may be formed on an inner wall of the first opening OP1. The portions described in relation to FIG. 5D may be equally applied to description of the protective layer PL. Hereinafter, the rightmost opening OP in FIGS. 5A to 5M will be mainly described.

Referring to FIG. 5H, a third opening OP3 may be formed in the preliminary stack structure pSTK. The third opening OP3 may be formed by etching a portion of the preliminary stack structure pSTK through the preliminary opening OPP, the first opening OP1, and the second opening OP2. The third opening OP3 may extend in a downward direction from the second opening OP2. While the third opening OP3 is being formed, sidewalls of the preliminary opening OPP, the first opening OP1, and the second opening OP2 may be protected by the protective layer PL. It may be understood that the preliminary opening OPP, the first opening OP1, the second opening OP2, and the third opening OP3 are included in an opening OP.

Referring to FIG. 5I, while the third opening OP3 is being formed, a protective layer PL may be formed along a sidewall of the third opening OP3. The protective layer PL may extend along an inner wall of the opening OP. The protective layer PL may cover a sidewall of the opening OP. The protective layer PL might not cover a bottom surface of the opening OP.

Referring to FIG. 5J, the photoresist PR and the second hard mask layer HM2 may be removed, and the protective layer PL in the opening OP may be removed. For example, through the opening OP, the protective layer PL may be removed through an isotropic wet etching process. As the protective layer PL is removed, the sidewall of the opening OP may be exposed.

Referring to FIG. 5K, a spacer layer SPL may be formed along the inner wall and the bottom surface of the opening OP. For example, the spacer layer SPL may be formed along surfaces of the inner wall and the bottom surface of the opening OP. The preliminary stack structure pSTK might not be exposed to the outside. The spacer layer SPL may be formed of an insulating layer (e.g., an oxide layer, a nitride layer, an oxynitride layer, or an oxide layer doped with a metal).

A sacrificial pillar FP may be formed inside the spacer layer SPL. The sacrificial pillar FP may fill the opening OP. The spacer layer SPL may surround a sidewall and a bottom surface of the sacrificial pillar FP. The sacrificial pillar FP may be formed of tungsten (W), cobalt (Co), nickel (Ni), molybdenum (Mo), silicon (Si) or poly-silicon (poly-Si) or may be formed of a combination of at least two thereof.

Referring to FIG. 5L, the second material layers SF of the preliminary stack structure pSTK may be replaced with third material layers CD. While openings OP are being filled with spacer layers SPL and sacrificial pillars FP, the second material layers SF may be removed, and the third material layers CD may be filled. As the third material layers CD are filled between the first material layers IL, a stack structure STK may be formed. The stack structure STK may include the first material layers IL and the third material layers CD, which are alternately stacked. The third material layers CD may be formed of tungsten (W), cobalt (Co), nickel (Ni), molybdenum (Mo), silicon (Si) or poly-silicon (poly-Si) or may be formed of a combination of at least two thereof.

After the second material layers SF are replaced with the third material layers CD, the sacrificial pillars FP may be removed. As the sacrificial pillars FP are removed, pillar openings PP may be formed in the openings OP.

Referring to FIG. 5M, a portion of each of the spacer layers SPL may be removed. Bottom surfaces of the spacer layers SPL may be etched. For example, the bottom surfaces of the spacer layers SPL may be etched through the pillar openings PP. As the bottom surfaces of the spacer layers SPL are etched, spacers SP may be formed, which expose the third material layers CD. The spacers SP may be formed along sidewalls of the openings OP. Since the spacers SP do not cover bottom surfaces of the openings OP, the third material layers CD may be exposed.

Contact plugs CT may be formed in the openings OP. The contact plugs CT may be in contact with the third material layers CD exposed through the openings OP, respectively. The contact plugs CT may fill the spacers SP.

FIG. 6 is a view illustrating a structure of a memory device in accordance with another embodiment of the present disclosure.

When comparing FIG. 6 with FIG. 4A, each of the first and second sub-stack structures SUB1 and SUB2 may include two or more pairs of conductive layers CD and interlayer insulating layers IL. Openings OP may include a first opening OP1 in the second sub-stack structure SUB2 and a second opening OP2 in the first sub-stack structure SUB1. A width of a top end of the second opening OP2 may be greater than a width of a bottom end of the first opening OP1. Similarly to FIG. 6, each of the first and second sub-stack structures SUB1 and SUB2 may include three or more pairs of conductive layers CD and interlayer insulating layers IL.

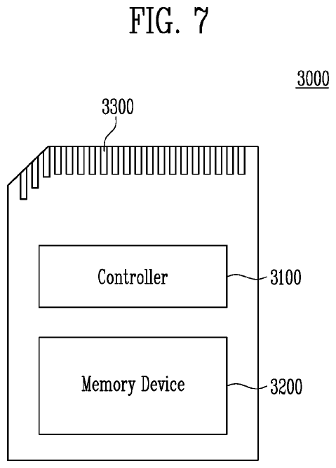

FIG. 7 is a diagram illustrating a memory card system to which the memory device of the present disclosure is applied.

Referring to FIG. 7, the memory card system 3000 may include a controller 3100, a memory device 3200, and a connector 3300.

The controller 3100 may be connected to the memory device 3200. The controller 3100 may access the memory device 3200. For example, the controller 3100 may control a program, read, or ease operation or may control a background operation of the memory device 3200. The controller 3100 may provide an interface between the memory device 3200 and a host. The controller 3100 may drive firmware for controlling the memory device 3200. For example, the controller 3100 may include components, such as a Random Access Memory (RAM), a processing unit, a host interface, a memory interface, and an error corrector.

The controller 3100 may communicate with an external device through the connector 3300. The controller 3100 may communicate with the external device (e.g., the host) according to a specific communication protocol. Exemplarily, the controller 3100 may communicate with the external device through at least one various communication protocol, such as a Universal Serial Bus (USB), a Multi-Media Card (MMC), an embedded MMC (eMMC), a Peripheral Component Interconnection (PCI), a PCI express (PCIe), an Advanced Technology Attachment (ATA), a Serial-ATA (SATA), a Parallel-ATA (PATA), a Small Computer System Interface (SCSI), an Enhanced Small Disk Interface (ESDI), an Integrated Drive Electronics (IDE), firewire, a Universal Flash Storage (UFS), Wi-Fi, Bluetooth, and NVMe. For example, the connector 3300 may be defined by at least one of the above-described various communication protocols.

The memory device 3200 may include memory cells and may be configured identically to the memory device 100 shown in FIG. 1.

The controller 3100 and the memory device 3200 may be integrated into a single semiconductor device to constitute a memory card. For example, the controller 3100 and the memory device 3200 may constitute a memory card, such as a personal computer (PC) card (Personal Computer Memory Card International Association (PCMCIA)), a Compact Flash (CF) card, a Smart Media Card (SM and SMC), a memory stick, a Multi-Media Card (MMC, RS-MMC, MMCmicro and eMMC), an SD card (SD, miniSD, microSD and SDHC), and a Universal Flash Storage (UFS).

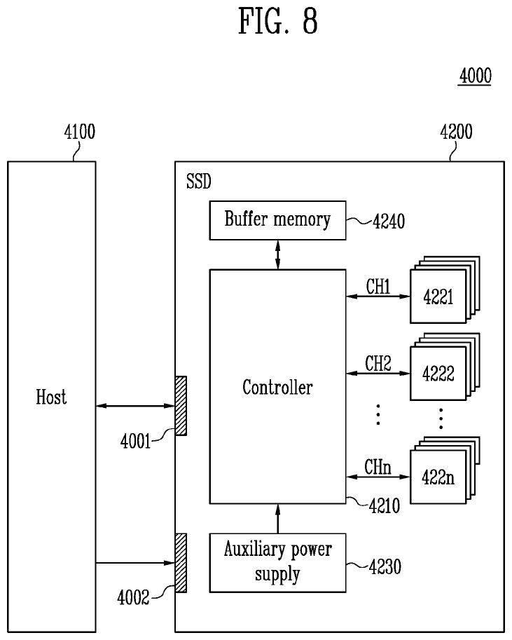

FIG. 8 is a diagram illustrating a Solid State Drive (SSD) system to which the memory device of the present disclosure is applied.

Referring to FIG. 8, the SSD system 4000 may include a host 4100 and an SSD 4200. The SSD 4200 may exchange a signal with the host 4100 through a signal connector 4001 and may receive power through a power connector 4002. The SSD 4200 may include a controller 4210, a plurality of memory devices 4221 to 422n, an auxiliary power supply 4230, and a buffer memory 4240.

The controller 4210 may control the plurality of memory devices 4221 to 422n in response to a signal received from the host 4100. Exemplarily, the signal may be a signal based on an interface between the host 4100 and the SSD 4200. For example, the signal may be a signal defined by at least one interface, such as a Universal Serial Bus (USB), a Multi-Media Card (MMC), an embedded MMC (eMMC), a Peripheral Component Interconnection (PCI), a PCI express (PCIe), an Advanced Technology Attachment (ATA), a Serial-ATA (SATA), a Parallel-ATA (PATA), a Small Computer System Interface (SCSI), an Enhanced Small Disk Interface (ESDI), an Integrated Drive Electronics (IDE), a firewire, a Universal Flash Storage (UFS), a WI-FI, a Bluetooth, and an NVMe.

The plurality of memory devices 4221 to 422n may include a plurality of memory cells configured to store data. Each of the plurality of memory devices 4221 to 422n may be configured identically to the memory device 100 shown in FIG. 1. The plurality of memory devices 4221 to 422n may communicate with the controller 4210 through channels CH1 to CHn.

The auxiliary power supply 4230 may be connected to the host 4100 through the power connector 4002. The auxiliary power supply 4230 may receive power input from the host 4100 and may charge the power. When the supply of power from the host 4100 is not smooth, the auxiliary power supply 4230 may provide power for the SSD 4200. Exemplarily, the auxiliary power supply 4230 may be located in the SSD 4200 or may be located outside of the SSD 4200. For example, the auxiliary power supply 4230 may be located on a main board and may provide auxiliary power to the SSD 4200.

The buffer memory 4240 may operate as a buffer memory of the SSD 4200. For example, the buffer memory 4240 may temporarily store data received from the host 4100 or data received from the plurality of memory devices 4221 to 422n or may temporarily store meta data (e.g., a mapping table) of the memory devices 4221 to 422n. The buffer memory 4240 may include volatile memories, such as a DRAM, an SDRAM, a DDR SDRAM, an LPDDR SDRAM, and a GRAM, or nonvolatile memories, such as a FRAM, a ReRAM, an STT-MRAM, and a PRAM.

In accordance with the present disclosure, a width difference between a top end and a bottom end of each of contact plugs included in the memory device is decreased, so that each contact plug can have a constant width. Accordingly, the operational reliability of the memory device can be improved.

While the present disclosure has been shown and described with reference to certain exemplary embodiments thereof, it will be understood by those skilled in the art that various changes in form and details may be made therein without departing from the spirit and scope of the present disclosure as defined by the appended claims and their equivalents. Therefore, the scope of the present disclosure should not be limited to the above-described exemplary embodiments but should be determined by not only the appended claims but also the equivalents thereof.

In the above-described embodiments, all steps may be selectively performed or part of the steps and may be omitted. In each embodiment, the steps are not necessarily performed in accordance with the described order and may be rearranged. The embodiments disclosed in this specification and drawings are only examples to facilitate an understanding of the present disclosure, and the present disclosure is not limited thereto. That is, it should be apparent to those skilled in the art that various modifications can be made on the basis of the technological scope of the present disclosure.

Meanwhile, the exemplary embodiments of the present disclosure have been described in the drawings and specification. Although specific terminologies are used here, those are only to explain the embodiments of the present disclosure. Therefore, the present disclosure is not restricted to the above-described embodiments and many variations are possible within the spirit and scope of the present disclosure. It should be apparent to those skilled in the art that various modifications can be made on the basis of the technological scope of the present disclosure in addition to the embodiments disclosed herein.

What is claimed is:

1. A memory device comprising:
a stack structure including a plurality of conductive layers and a plurality of interlayer insulating layers, which are alternately stacked along a first direction;
an opening extending in the first direction from at least one conductive layer, among the plurality of conductive layers, in the stack structure; and
a contact plug in the opening,
wherein the opening includes a protrusion portion protruding in a second direction intersecting the first direction.

2. The memory device of claim 1, wherein the opening includes a first opening and a second opening below the first opening.

3. The memory device of claim 2, wherein a width of a top end of the second opening is greater than a width of a bottom end of the first opening.

4. The memory device of claim 2, wherein a width of a top end of each of the first and second openings is greater than a width of a bottom end of each of the first and second openings.

5. The memory device of claim 2, wherein, due to the protrusion portion, a top end of each of the first and second openings protrudes into the stack structure as compared with a bottom surface of each of the first and second openings.

6. The memory device of claim 2, wherein the stack structure includes a first sub-stack structure including a first conductive layer and a first interlayer insulating layer, the first conductive layer being on top of the first interlayer insulating layer, on top of the at least one conductive layer and a second sub-stack structure including a second conductive layer and a second interlayer insulating layer, the second conductive layer being on top of the second interlayer insulating layer, on the top of the first sub-stack structure, and
wherein the second sub-stack structure includes the first opening, and
the first sub-stack structure includes the second opening.

7. The memory device of claim 6, wherein an interface between the first sub-stack structure and the second sub-stack structure corresponds to an interface between the second opening and the first opening.

8. The memory device of claim 6, wherein a portion of a top surface of the second opening is in contact with a bottom surface of the second interlayer insulating layer.

9. The memory device of claim 1, further comprising a spacer formed along an inner wall of the opening.

10. The memory device of claim 9, wherein the spacer covers a sidewall of the contact plug.

11. The memory device of claim 9, wherein the spacer allows the contact plug to be spaced apart from conductive layers and interlayer insulating layers, which are located above the at least one conductive layer, among the plurality of conductive layers and the plurality of interlayer insulating layers.

12. The memory device of claim 1, wherein the contact plug is in contact with a top surface of the at least one conductive layer.

13. The memory device of claim 1, wherein the contact plug includes a protrusion portion protruding in the second direction.

14. The memory device of claim 1, wherein a sidewall of the contact plug includes an uneven surface.

15. The memory device of claim 1, wherein a width of the contact plug at a first position is less than a width of the contact plug at a second position below the first position.
